(19) United States
(12) Patent Application Publication
(10) Pub. No.: US 2012/0052671 A1
(43) Pub. Date: Mar. 1, 2012

(54) NON-VOLATILE MEMORY DEVICE AND METHOD OF MANUFACTURING THE SAME

(76) Inventors: Choong-kee Seong, Seoul (KR); Kwang-bok Kim, Incheon (KR); Kyung-hyun Kim, Seoul (KR); Jae-jin Shin, Seoul (KR); Hyun-ho Son, Seoul (KR)

(21) Appl. No.: 13/191,571

(22) Filed: Jul. 27, 2011

(30) Foreign Application Priority Data
Aug. 26, 2010 (KR) 10-2010-0083066

(51) Int. Cl. H01L 21/28; H01L 21/302

(52) U.S. Cl. 438/591; 438/706; 257/E21.19; 257/E21.214

(57) ABSTRACT

A method of manufacturing a non-volatile memory device and a non-volatile memory device are provided. The method includes: providing a substrate on which a plurality of charge storage layers that are electrically separated from each other by device isolation layers are formed; recessing the device isolation layers such that an uppermost portion of the device isolation layers is lower than an uppermost portion of the charge storage layers; and dry cleaning first and second sides of each of the charge storage layers that are exposed by the device isolation layers by using a cleaning agent including NF₃ gas.

### CROSS-REFERENCE TO RELATED APPLICATIONS

This application claims priority under 35 USC §119 to Korean Patent Application No. 10-2010-0083066, filed on Aug. 26, 2010, in the Korean Intellectual Property Office, the disclosure of which is incorporated herein in its entirety by reference.

### BACKGROUND

The disclosed embodiments relate to a semiconductor memory device and a method of manufacturing the same, and more particularly, to a method of manufacturing a non-volatile memory device having a high integration density.

Although electronic devices are increasingly reduced in size, they are required to process a large amount of data. Thus, an integration density of non-volatile memory devices for use in such electronic devices needs to be increased. However, since non-volatile memory devices use relatively high voltages, it is difficult to increase the integration density due to interference occurring in adjacent memory cells.

### SUMMARY

Example embodiments provide a non-volatile memory device and a method of manufacturing a non-volatile memory device by which interference between adjacent memory cells may be reduced during programming or erasing operations.

According to one embodiment, there is provided a method of manufacturing a non-volatile memory device, the method including: providing a substrate on which a plurality of charge storage layers that are electrically separated from each other by device isolation layers are formed; recessing the device isolation layers such that an uppermost portion of the device isolation layers is lower than an uppermost portion of the charge storage layers; and dry cleaning first and second sides of each of the charge storage layers that are exposed by the device isolation layers by using a cleaning agent including NF₃ gas.

An upper width of each of the charge storage layers may become less than a lower width of each of the charge storage layers due to the dry cleaning.

The cleaning agent may further include NH₃ gas, wherein the amount of the NF₃ gas is greater than that of the NH₃ gas.

The volume ratio of the NF₃ gas to the NH₃ gas may be in a range of 5:1 to 10:1.

Each of the amounts of the NF₃ gas and the NH₃ gas may be greater than 100 sccm and 10 sccm, respectively.

The dry cleaning may be performed at a temperature in a range of 30° C. to 60° C.

The method may further include removing an oxide from the surface of the charge storage layers before the dry cleaning.

The removing of the oxide from the surface of the charge storage layers may be performed using hydrofluoric acid (HF).

The charge storage layers may be floating gates including poly-silicon.

The cleaning agent may have an etch selectivity with respect to the charge storage layers which is greater than that with respect to the device isolation layers.

An etching ratio for the cleaning agent between the charge storage layers and the device isolation layers may be equal to or greater than 4:1.

The recessing of the device isolation layers may be performed using an etchant including HF gas and NH₃ gas.

The recessing of the device isolation layers may include: a first recessing by which the device isolation layers are recessed to a predetermined depth; and a second recessing by which the device isolation layers are recessed to be lower than the uppermost portion of the charge storage layers.

The dry cleaning may be performed between the first recessing and the second recessing.

The providing of the substrate may include: forming a stack structure in which a pad layer and a mask layer are sequentially stacked on the substrate; forming trenches in the substrate by partially etching the stack structure and the substrate; forming device isolation layers in the trenches; and removing the pad layer and the mask layer at both side of the device isolation layers and forming a plurality of charge storage layers electrically separated from each other by the device isolation layers.

The providing of the substrate may include: sequentially stacking a tunneling insulating layer and a charge storage layer on the substrate; forming trenches in the substrate by partially etching the tunneling insulating layer, the charge storage layer, and the substrate; and forming device isolation layers in the trenches to electrically separate the charge storage layers from each other.

The method may further include: forming a blocking insulating layer on the charge storage layer and the device isolation layer along a height difference; and forming a gate electrode layer that fills spaces between the charge storage layers on the blocking insulating layer.

In futher embodiment, there is provided a method of manufacturing a non-volatile memory device, the method including: providing a substrate on which a plurality of charge storage layers that are electrically separated from each other by device isolation layers are formed; and recessing the device isolation layers such that an uppermost portion of the device isolation layers is lower than an uppermost portion of the charge storage layers, wherein first and second sides of each of the charge storage layers are etched while recessing the device isolation layers.

The recessing of the device isolation layers may be performed using a cleaning agent including NF₃ gas and NH₃ gas.

In another embodiment, there is provided a a non-volatile memory device, thememory device includes a substrate, a first device isolation layer, a second device isolation layer and a charge storage layer. The substrate includes a top portion and a bottom portion. The first device isolation layer and the second device isolation layer are disposed with a predetermined distance, apart from each other in a first direction. The charge storage layer is disposed on the substrate between the first and second device isolation layers, and connected to part of each of the first and second device isolation layers. The charge storage layer includes that slope inward toward a top of the charge storage layer in the first direction. The slope of of each sidewall above the top surface of each of the first and second device isolation layers to the top of the charge storage layer is a smooth curve.

### BRIEF DESCRIPTION OF THE DRAWINGS

Exemplary embodiments will be more clearly understood from the following detailed description taken in conjunction with the accompanying drawings in which:

FIG. 1 is a layout diagram of a portion of a memory cell array included in a non-volatile memory device according to an exemplary embodiment;

FIG. 2 is a perspective view of the non-volatile memory device of FIG. 1;

FIGS. 3A to 3I are cross-sectional views of the non-volatile memory device of FIG. 2 for describing a method of manufacturing the non-volatile memory device according to an exemplary embodiment;

FIG. 4 is a perspective view of a non-volatile memory device according to example embodiments;

FIGS. 5A to 5C are cross-sectional views of the non-volatile memory device of FIG. 4 for describing a method of manufacturing the non-volatile memory device according to an exemplary embodiment;

FIG. 6 is a graph for describing a threshold voltage characteristic of a non-volatile memory device according to example embodiments;

FIG. 7 is a schematic block diagram of a non-volatile memory device according to example embodiments;

FIG. 8 schematically shows a memory card according to example embodiments; and

FIG. 9 is a block diagram illustrating an electronic system according to example embodiments.

### DETAILED DESCRIPTION OF THE EMBODIMENTS

Hereinafter, the exemplary embodiments will be described in detail with reference to the attached drawings.

The exemplary embodiments may, however, be embodied in many different forms and should not construed as being limited to those set forth herein.

It will be understood that when an element or a layer is referred to as being “on” another element or layer, the element or layer can be directly on another element or layer or intervening elements or layers. In the accompanying drawings, thicknesses and sizes of layers and regions are exaggerated for clarity, and like reference numerals denote like elements. As used herein, the term “and/or” includes any one of at least one of combinations of one or more of the associated listed items.

The terms used herein are used to describe embodiments, and not to limit the inventive concept. A singular form may include a plural form, unless otherwise defined. The term such as “comprise,” “includes,” and/or “comprising” specify the existence of mentioned shapes, numbers, steps, operations, elements, parts, and/or groups thereof, and do not exclude existence or addition of at least one other shapes, numbers, steps, operations, elements, parts, and/or groups thereof.

Hereinafter, the various example embodiments will be described more fully with reference to the accompanying drawings, in which embodiments are shown. In the drawings, the illustrated features may be changed due to, for example, the manufacturing technology and/or tolerance. Accordingly, it should be understood that the example embodiments are not limited to the drawings but include modifications of the features of elements caused due to, for example, the manufacture.

Also, though terms like a first, a second, and a third are used to describe various elements, regions, and layers in various embodiments, the elements, regions, and the layers are not limited to these terms. Unless indicated as otherwise, these terms are used only to discriminate one element, region, or layer from another element, region, or layer.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “planar,” or “coplanar,” as used herein when referring to orientation, location, shapes, sizes, amounts, or other measures do not necessarily mean an exactly identical orientation, location, shape, size, amount, or other measure, but are intended to encompass nearly identical orientation, location, shapes, sizes, amounts, or other measures within acceptable variations that may occur, for example, due to manufacturing processes.

A method of manufacturing a non-volatile memory device according to exemplary embodiments may be applied to manufacturing non-volatile memory devices, for example, a read-only memory (ROM), an erasable programmable ROM (EPROM), an electrically erasable and programmable ROM (EEPROM), a flash memory device, and a ferroelectric material memory device. The method of manufacturing a non-volatile memory device according to the exemplary embodiments may be applied to any memory device including a gate electrode. The term “device” may include, for example, a chip, package or package-on-package, etc.

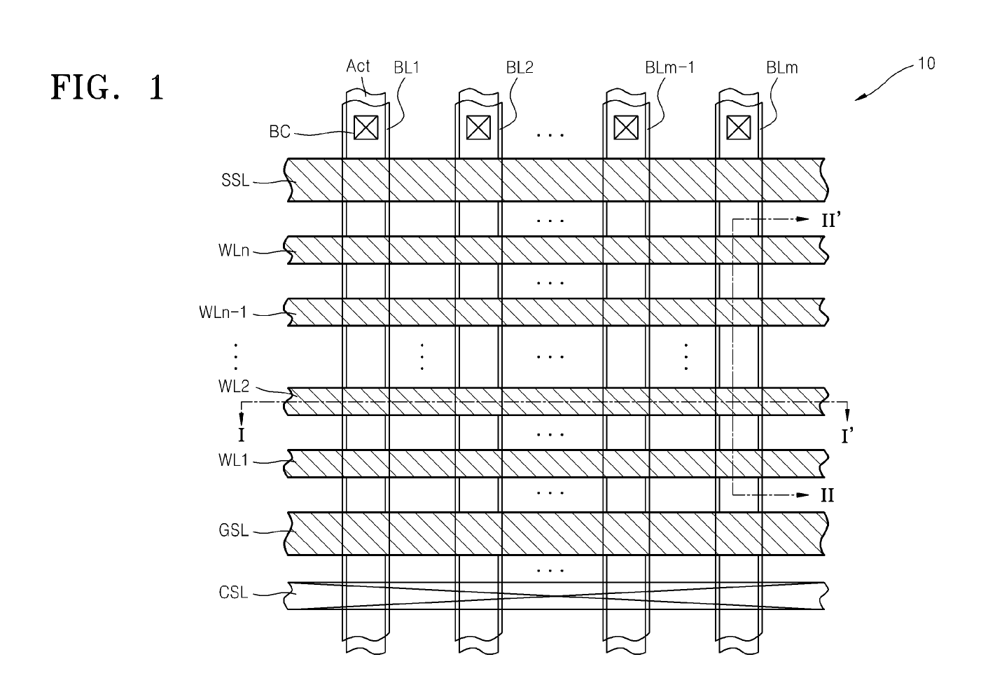

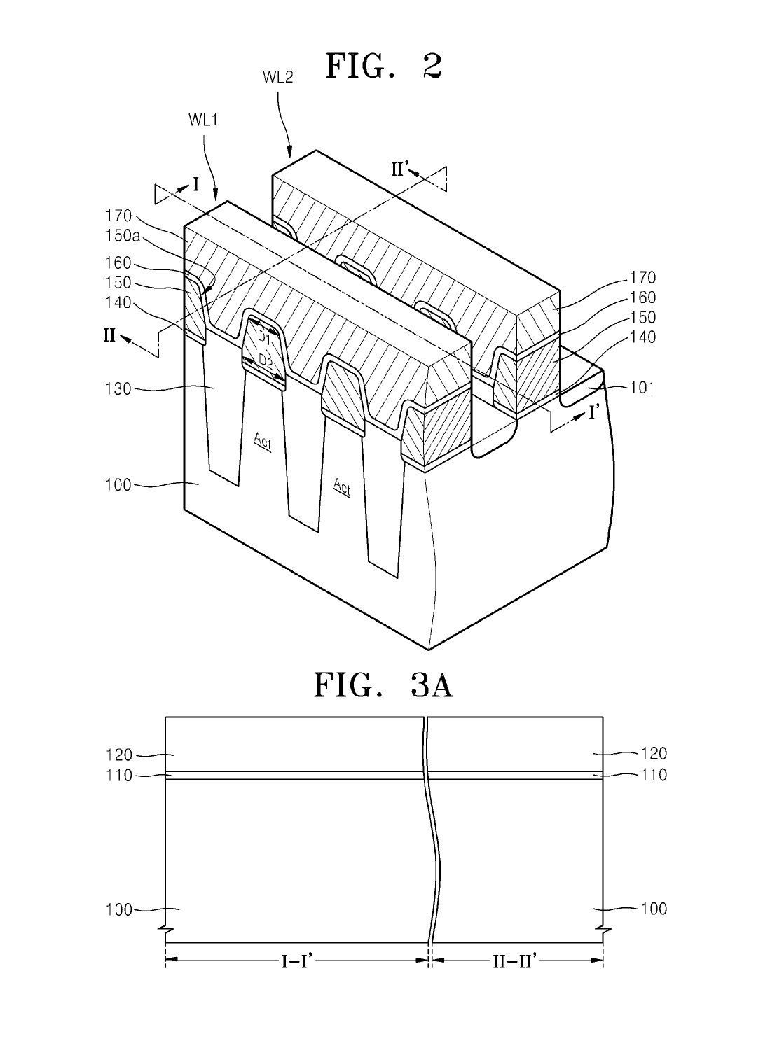

FIG. 1 is a layout diagram of a portion of a memory cell array 10 included in a non-volatile memory device according to an exemplary embodiment. FIG. 2 is a perspective view of the non-volatile memory device of FIG. 1.

In particular, in one embodiment, FIG. 1 represents a layout diagram of a NAND flash memory as the non-volatile memory device. Hereinafter, the disclosure will be described with reference to the NAND flash memory device.

FIG. 2 may not show some elements of the non-volatile memory device of FIG. 1. For example, bit lines of the non-volatile memory device are not shown in FIG. 2.

Referring to FIGS. 1 and 2, the memory cell array 10 may include a plurality of active regions Act that are defined by device isolation layers 130 formed in a substrate 100. The active regions Act may be parallel to each other to form a line pattern.

A string selection line SSL and a ground selection line GSL may be disposed on the active regions Act in a direction across, (e.g., perpendicular to) the active regions Act. A plurality of word lines WL1, WL2, WLn−1, and WLn may be disposed between the string selection line SSL and the ground selection line GSL in a direction across the active regions Act. The string selection line SSL, the ground selection line GSL, and the word lines WL1, WL2, WLn−1, and WLn may be parallel to one another.

Impurity regions 101 may be formed in portions of the active regions Act adjacent to both sides of the word lines WL1, WL2, WLn−1, and WLn, the string selection line SSL, and the ground selection line GSL. As a result, a string selection transistor, a plurality of memory cell transistors, and a ground selection transistor, which are connected in series, may be formed. The string selection transistor, the ground selection transistor, and the memory cell transistors disposed therebetween may form one unit memory string.

Active regions Act that are disposed close to the string selection line SSL and opposite to the ground selection line GSL may be defined as a drain region of the string selection transistor. In addition, active regions Act that are disposed close to the ground selection line GSL and opposite to the string selection line SSL may be defined as a source region of the ground selection transistor.

The substrate 100 may include, for example, a substrate and/or an epitaxial layer, a silicon-on-insulator (SOI) layer, and/or a semiconductor-on-insulator (SEOI) layer.

Each of the word lines WL1, WL2, WLn−1, and WLn may include a tunneling insulating layer 140, a charge storage layer 150, a blocking insulating layer 160, and a gate electrode layer 170, which are sequentially stacked on the substrate 100 in a direction across the active region Act.

The tunneling insulating layer 140 and the charge storage layer 150 may be separated from each other to form separate floating gate structures for respective memory cell transistors adjacent each other in extension directions of the word lines WL1, WL2, WLn−1, and WLn. The tunneling insulating layer 140 may be, for example, a silicon oxide layer. The charge storage layer 150 stores charges and may be a charge trap layer or conductive layer. The charge storage layer 150 may include, for example, a semiconductor doped with a dopant, for example, doped poly-silicon. The charge storage layer 150 for each transistor is electrically insulated from the charge storage layer 150 for other transistors by the device isolation layer 130, the tunneling insulating layer 140 and the blocking insulating layer 160.

Sidewalls 150a of the charge storage layer 150 for each transistor have slopes having a predetermined angle with respect to extension directions of the word lines WL1, WL2, WLn−1, and WLn (the extension direction may be referred to herein as a first direction). Accordingly, an upper width Dl of the charge storage layer 150 for each transistor may be less than a lower width D2 thereof.

The blocking insulating layer 160 may be shared by adjacent memory cell transistors in extension directions of the word lines WL1, WL2, WLn−1, and WLn. The blocking insulating layer 160 may be, for example, a silicon oxide layer, a silicon nitride layer, a stack thereof or an oxide-nitride-oxide (ONO) layer. Alternatively, the blocking insulating layer 160 may include a high k material.

The gate electrode layer 170 may be an electrode that controls programming and erasing operations. The gate electrode layer 170 may be a part of the word lines WL1, WL2, WLn−1, and WLn. In one embodiment, the gate electrode layer 170 may be formed to be connected between adjacent cell transistors in extension directions of the word lines WL1, WL2, WLn−1, and WLn. The gate electrode layer 170 may be a conductive layer including a doped semiconductor, e.g., metal silicide. The gate electrode layer 170 may include, for example, doped poly-silicon.

The string selection line SSL and/or the ground selection line GSL may have the same structure as that of the word lines WL1, WL2, WLn−1, and WLn in regions crossing the active regions Act. Alternatively, the charge storage layer 150 and the gate electrode layer 170 may be electrically connected to each other in the string select line SSL and/or the ground selection line GSL to form a single electrode for each of those lines. In certain embodiments, the widths of the string selection line SSL and the ground selection line GSL may be greater than those of the word lines WL1, WL2, WLn−1, and WLn. However, the disclosure is not limited thereto.

A bit line plug (not shown) that is connected to a drain region of the string selection line SSL may be formed. Bit lines BL1, BL2, BLm−1, and BLm may be disposed to cross the word lines WL1, WL2, WLn−1, and WLn and connected to the bit line plug. The bit lines BL1, BL2, BLm−1, and BLm may be parallel to the active regions Act.

In the non-volatile memory device according to the present embodiment, since the sidewalls 150a of the charge storage layer 150 for each transistor have slopes, such that adjacent sidewalls of adjacent charge storage layers 150 slope away from each other, intervals between adjacent charge storage layers 150 increase, thereby improving interference characteristics between adjacent memory cells.

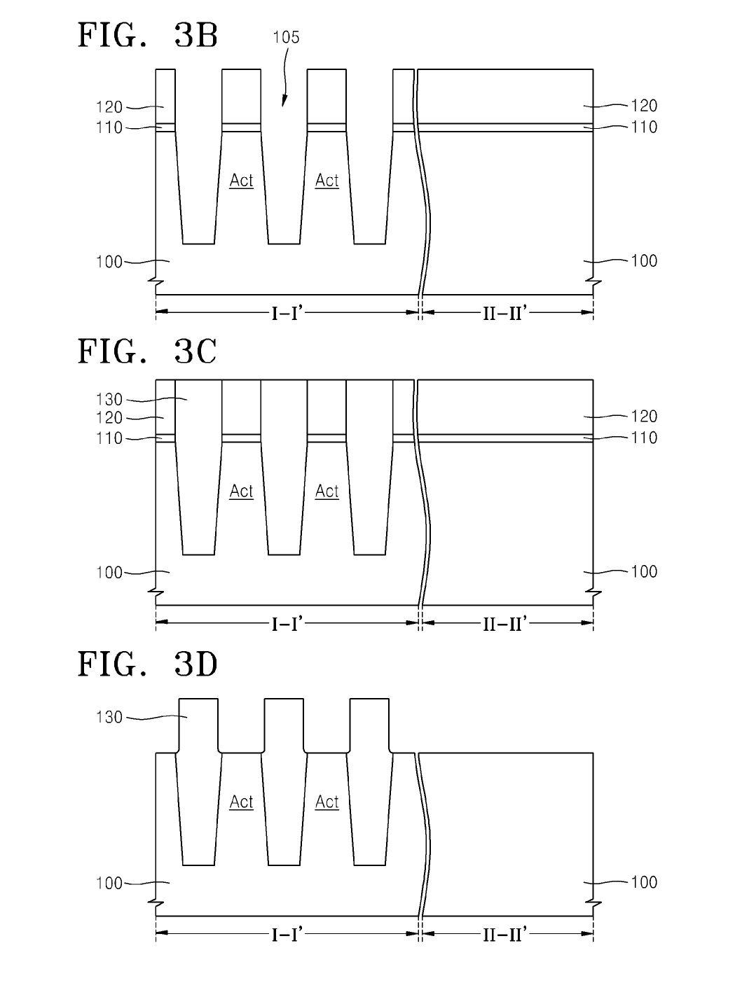

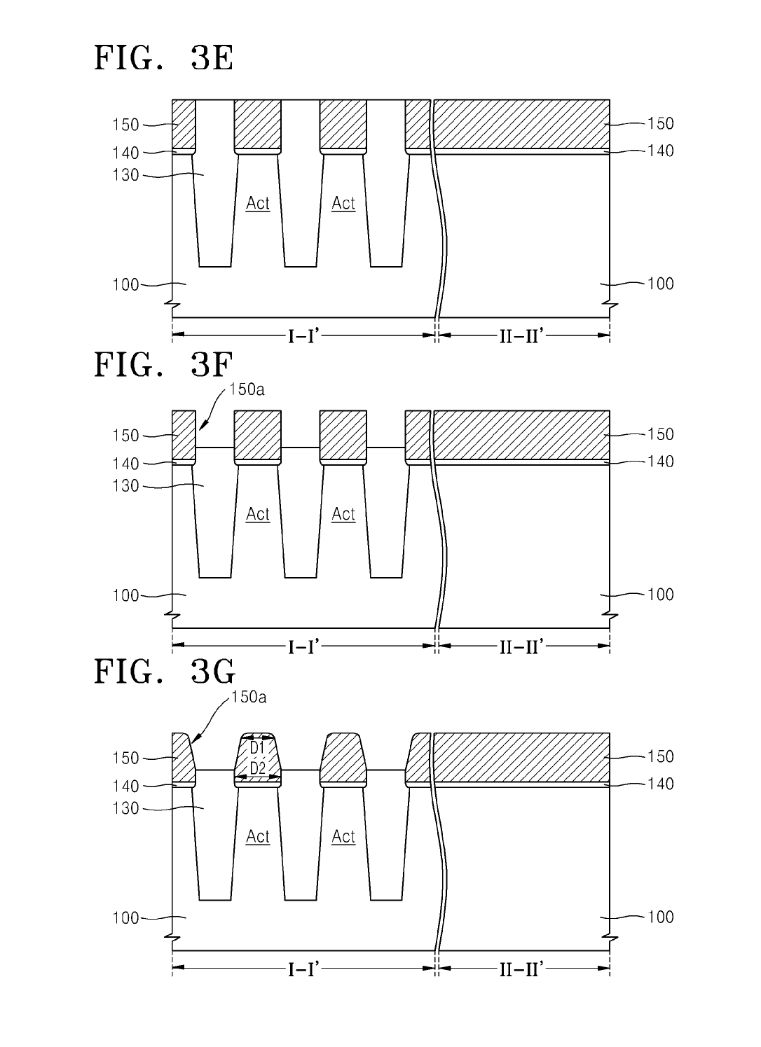

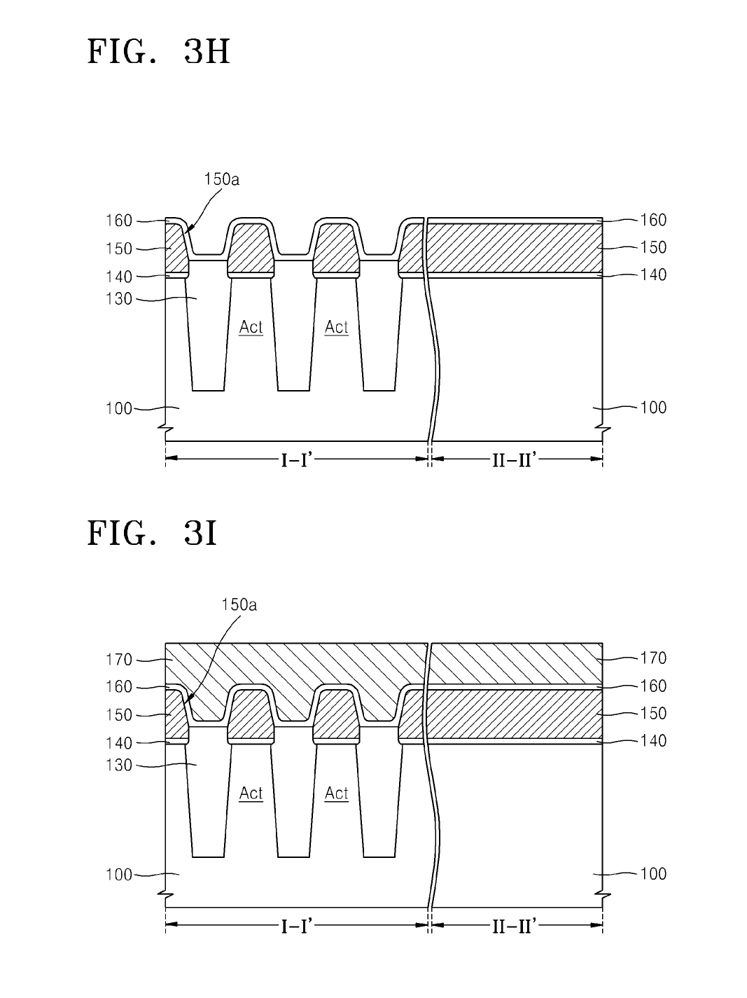

FIGS. 3A to 3I are cross-sectional views of the non-volatile memory device of FIG. 2 for describing the non-volatile memory device and a method of manufacturing the non-volatile memory device. FIGS. 3A to 3I are respectively cross-sectional views taken along lines I-I′ and II-II′ of FIGS. 1 and 2.

Referring to FIG. 3A in one embodiment, a pad layer 110 and a mask layer 120 are formed on the substrate 100. The substrate 100 includes a top portion and a bottom portion. The pad layer 110 may be, for example, a silicon oxide layer. The pad layer 110 may be formed, for example, using a thermal oxidation process or chemical vapor deposition (CVD) process. The mask layer 120 may be, for example, a hard mask layer such as a silicon nitride layer.

In one embodiment, the substrate 100 includes wells (not shown) generated by an ion implantation process. The substrate 100 may include cell regions and peripheral regions. The pad layer 110 and the mask layer 120 may be formed in the cell regions and peripheral regions. The pad layer 110 helps to prevent damage or stress applied to the substrate 100 while the mask layer 120 is deposited.

Referring to FIG. 3B, the pad layer 110 and the mask layer 120 are patterned using a photoresist pattern (not shown) to expose regions where trenches 105 will be formed.

Then, the substrate 100 is etched using the patterns of the pad layer 110 and the mask layer 120 to form the trenches 105. The trench 105 may be formed using an anisotropic etching process, for example, a plasma etch process. After the trenches 105 are formed, an ion implantation process may further be performed to enhance insulating properties.

Referring to FIG. 3C, an insulating material (not shown) is filled in the trenches 105 on the substrate 100. The insulating material may be filled using, for example, a CVD process. The insulating material may include, for example, an oxide, nitride or any combination thereof. For example, the insulating material may form a complex layer including a buffered oxide layer, a trench liner nitride layer, and a filled oxide layer. The insulating material may also be a high temperature oxide (HTO), high density plasma (HDP), tetra ethyl ortho silicate (TEOS), boron-phosphorus silicate glass (BPSG), or undoped silicate glass (USG). After the insulating material layer is filled, an annealing process may further be performed to increase the density of the layer.

In one embodiment, all of the trenches 105 are filled with the insulating material, and a planarization process is then performed. The insulating material 130 for each trench may be disposed a predetermined distance apart from the insulating material 130 for an adjacent trench, as shown in FIG. 3C. The planarization process may be a chemical mechanical polishing (CMP) process. In one embodiment, the planarization process is performed using the mask layer 120 as a stop layer, and the mask layer 120 is also be partially removed by the planarization process.

The trenches 105 (FIG. 3B) are filled by the CVD process and the planarization process to form device isolation layers 130 (FIG. 3C) having the same height as the mask layer 120. The active regions Act may be defined by the device isolation layers 130.

Referring to FIG. 3D, the pad layer 110 and the mask layer 120 are removed. While the pad layer 110 and the mask layer 120 are removed, sidewalls of the device isolation layers 130 may be partially eroded.

If the mask layer 120 is a silicon nitride layer, and the pad layer 110 is a silicon oxide layer, the mask layer 120 may be etched first using etching selectivity to silicon nitride. For example, the mask layer 120 may be removed by a wet etching process using phosphoric acid (H₃PO₄). Then, the pad layer 110 may be removed using a buffered oxide etchant (BOE) prepared by mixing hydrofluoric acid (HF) with ammonium fluoride (NH₄F).

Referring to FIG. 3E, the tunneling insulating layer 140 and the charge storage layer 150 are formed on the exposed substrate 100. For example, the tunneling insulating layer 140 may be formed by a thermal oxidation process. The tunneling insulating layer 140 may include a silicon oxide layer or a high-k oxide layer such as an oxide layer of hafnium (Hf) or zirconium (Zr). In one embodiment, the tunneling insulating layer 140 has a thickness in the range of 10 Å to 100 Å.

Then, the charge storage layer 150 is formed on the tunneling insulating layer 140. The charge storage layer 150 may be formed, for example, using a deposition and planarization process. By the planarization process, a plurality of charge storage layers 150 that are separated from each other by the device isolation layers 130 are formed.

The charge storage layers 150 may include a conductive material, for example, doped poly-silicon, metal, and metal silicide, or any combination thereof. If the charge storage layers 150 include poly-silicon, a poly-silicon that is not doped with impurities may be deposited using a low pressure chemical vapor deposition (LPCVD) process and then doped with arsenic (As) or phosphorous (P) using an ion implantation process. Alternatively, in-situ doped poly-silicon with impurities may be deposited.

As described above, if a conductive material is used in the charge storage layers 150, a typical flash memory that is a floating gate type non-volatile memory device may be formed. On the other hand, if an insulating material is used in the charge storage layers 150, a charge trap type flash memory that is a floating trap type non-volatile memory device may be formed.

Referring to FIG. 3F, the device isolation layers 130 are subjected to a recess process. Due to the recess process, sidewalls 150a of the charge storage layers 150 are exposed. The upper surface of the recessed device isolation layers 130 may be higher than the upper surface of the substrate 100, which includes active regions Act at both sides thereof. As a result, in one embodiment, the device isolation layers 130 connect to and contact the charge storage layers 150 (e.g., at sidewalls 150a).

On the other hand, the upper surface of the recessed device isolation layers 130 may be lower than the upper surface of the substrate 100, which includes active regions Act at both sides thereof. As such, the height of the upper surface of the recessed device isolation layers 130 may vary.

The recess process may include, for example, an anisotropic etching process. If the device isolation layers 130 include an oxide, the etching process may be performed at a temperature, for example, equal to or less than 30° C. by using hydrofluoric acid (HF) gas and/or ammonia (NH₃) gas. The etching process may be performed by two sub-processes to improve etching efficiency by removing by-products generated during the etching process.

Referring to FIG. 3G, the sidewalls 150a of the charge storage layers 150 exposed by the recess process are partially removed. Accordingly, the sidewalls 150a of the charge storage layers 150 have slopes. For example, each of the slopes of the sidewalls 150a may slope inward toward a top in a width direction of the charge storage layers 150. In addition, the slope of the sidewalls may be a continuous, constant, or nearly constant slope (i.e., a smooth curve) that does not have abrupt changes between a lower width D2 and an upper width Dl of the charge storage layers 150. Accordingly, an upper width D1 of the charge storage layers 150 may be less than a lower width D2 thereof. In one embodiment, the width ratio of D2 to D1 may be, for example, 1.9:1 to 1.5:1 (e.g., in one embodiment, the ratio is 1.7:1). Thus, an interval between adjacent charge storage layers 150 increases. In one embodiment, D1 is a width at a top surface of a charge storage layer 150 for a particular transistor (e.g., floating gate of a memory cell), and D2 is a width of the charge storage layer 150 at a height coplanar with a top surface of device isolation layers 130.

According to the present embodiment, the sidewalls 150a may be removed by a dry cleaning process using NF₃ gas and NH₃ gas resulting in a smooth curve slope, as described above. The dry cleaning according to the present embodiment is a dry etching process and may use plasma (e.g., remote plasma), to activate the NF₃ gas and the NH₃ gas. For example, the plasma power may equal to or greater than 30 W.

In one embodiment, the sidewalls 150a may be removed by a dry cleaning process. The sidewalls 150a may be removed without a separate mask layer. The sidewalls 150a may be removed, for example, using a cleaning agent having an etch selectivity with respect to the charge storage layers 150, which is greater than that with respect to the device isolation layers 130. For example, under the same etching process, more or a higher percentage of material for the charge storage layers 150 may be removed than for the device isolation layers 130.

The dry cleaning may be performed, for example, at a temperature equal to or less than 60° C. using nitrogen trifluoride (NF₃) gas and/or ammonia (NH₃) gas. The NF₃ gas may be supplied, for example, at a rate of 100 sccm or greater, and the NH₃ gas may be supplied at a rate of 10 sccm or greater. In one embodiment, the amount of the NF₃ gas used during the dry cleaning is greater than that of the NH₃ gas. The volume ratio of the NF₃ gas to the NH₃ gas may be, for example, in the range of 3:1 to 15:1 (e.g., in one embodiment, the ratio is 10:1). The dry cleaning may be performed, for example, at a pressure in the range of 2 Torr to 5 Torr (e.g., in one embodiment, the ratio is 3 Torr) and may be performed for a time period such as, for example, 10 seconds to 80 seconds.

Etching characteristics of the NF₃ gas and the NH₃ gas to silicon oxide (SiO₂) are well known in the art. However, according to one embodiment, conductive materials such as poly-silicon are etched using these gases. According to an etching mechanism of the NF₃ gas and the NH₃ gas with respect to silicon oxide (SiO₂), the NF₃ gas reacts with the NH₃ gas to produce NH₄F and NH₄F.HF. The NH₄F and NH₄F.HF react with SiO₂ to produce solid phase (NH₄)₂SiF₆ and H₂O. The (NH₄)₂SiF₆ is evaporated at a high temperature and thus may be easily removed.

As described above, the NF₃ gas and the NH₃ gas have a high etch selectivity with respect to silicon oxide. However, if the amount of the NF₃ gas is greater than the NH₃ gas, they have a higher etch selectivity with respect to poly-silicon than that with respect to the silicon oxide. In other words, in one embodiment, these gases have etching selectivity to poly-silicon. The etching selectivity of poly-silicon to silicon oxide may be, for example, about 4:1.

In further embodiment, the dry cleaning may be performed during the recess process of the device isolation layers 130 described above with reference to FIG. 3F. For example, if the recess process is performed by two sub-processes, the dry cleaning may be performed after a first recess process. Then, a second recess process may be performed. In this regard, a native oxide layer that may be formed on the surface of the charge storage layer 150 may be removed by the first recess process. Accordingly, during the dry cleaning process, the etching rate of the poly-silicon may further be increased.

In another embodiment, an additional process by which the native oxide layer that may be formed on the surface of the charge storage layer 150 is removed may be performed before the dry cleaning process. The native oxide layer may be removed using the HF and/or NH₃ gas.

In another embodiment, an additional recess process of the device isolation layers 130 may be simultaneously performed by the dry cleaning. Alternatively, the recess of the device isolation layers 130 and the removal of the sidewalls 150a of the charge storage layers 150 may be simultaneously performed by a single process. This is because the NF₃ gas and the NH₃ gas may also etch the oxide layer that forms the device isolation layers 130.

Referring to FIG. 3H, the blocking insulating layer 160 is formed on the device isolation layer 130 and the charge storage layer 150. The blocking insulating layer 160 may be deposited using, for example, atomic layer deposition (ALD) or CVD. The blocking insulating layer 160 may be, for example, a silicon oxide layer, a silicon nitride layer, or a stack thereof. For example, the blocking insulating layer 160 may be an oxide-nitride-oxide (ONO) layer.

As a design rule with respect to components of a semiconductor memory device is reduced, the intervals between the charge storage layers 150 may be reduced. Accordingly, if spaces between the charge storage layers 150 are filled with the blocking insulating layer 160, a gate electrode layer 170 (FIG. 3I) cannot be formed between the charge storage layers 150 in a subsequence process. Thus, coupling characteristics of the non-volatile memory device may deteriorate.

However, according to the disclosed embodiments, since the sidewalls 150a of the charge storage layers 150 have slopes, the interval between adjacent charge storage layers 150 increases. Thus, the blocking insulating layer 160 is formed to conformally cover the charge storage layers 150. Thus, coupling characteristics of the non-volatile memory device may not deteriorate.

Referring to FIG. 3I, the gate electrode layer 170 is formed on the blocking insulating layer 160. The gate electrode layer 170 may be deposited, for example, using a CVD or physical vapor deposition (PVD) process. In one embodiment, the gate electrode layer 170 is a control gate electrode if the memory device is a flash memory including a floating gate. In this regard, the gate electrode layer 170 may include poly-silicon, metal silicide, or metal. The gate electrode layer 170 may be a single layer or a complex layer.

As the integration density of semiconductor memory devices increases, intervals between adjacent memory cell transistors decrease, and thus adjacent charge storage layers 150 become closer. However, according to the present embodiments, since the sidewalls 150a of the charge storage layers 150 have slopes, intervals between the adjacent charge storage layers 150 increase. Thus, even if an aspect ratio increases, the gate electrode layer 170 may be deposited without voids, and accordingly reliability of the memory device may be improved.

Then, the tunneling insulating layer 140, the charge storage layer 150, the blocking insulating layer 160, and the gate electrode layer 170 which are sequentially formed are patterned to form word lines WL1, WL2, WLn−1, and WLn as shown in FIGS. 1 and 2. The word lines WL1, WL2, WLn−1, and WLn may be formed in a direction across the active regions Act as a line. Subsequently, an ion implantation process may be performed to form impurity regions 101 (FIG. 2) in the substrate 100 at both sides of the word lines WL1, WL2, WLn−1, and WLn. According to these processes, the non-volatile memory device shown in FIG. 2 is formed.

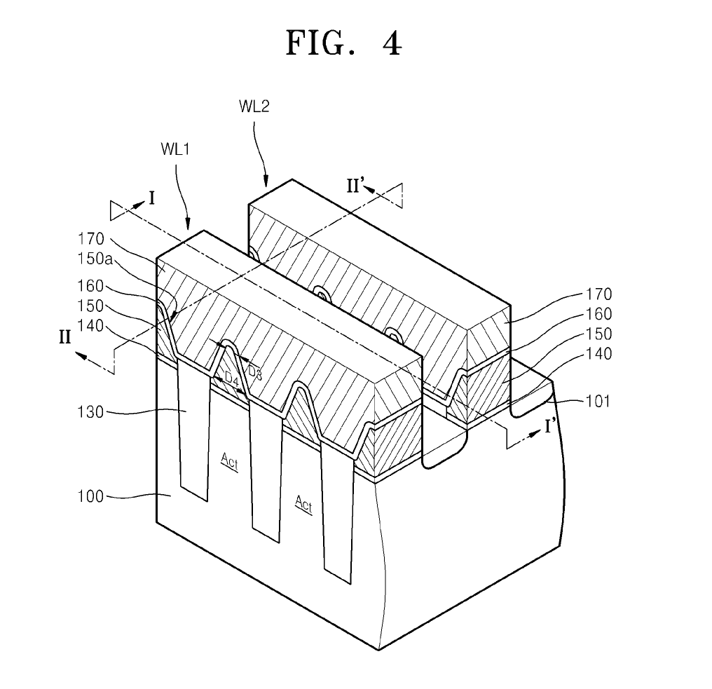

FIG. 4 is a perspective view of a non-volatile memory device according to another embodiment.

In FIG. 4, like reference numerals shown in FIG. 2 denote like elements. Thus, descriptions thereof will be omitted here. Referring to FIGS. 1 and 4, the upper surface of the device isolation layers 130 may be lower than that shown in FIG. 2. In other words, the upper surface of the device isolation layers 130 may be closer to the upper surface of the active regions Act of the substrate 100.

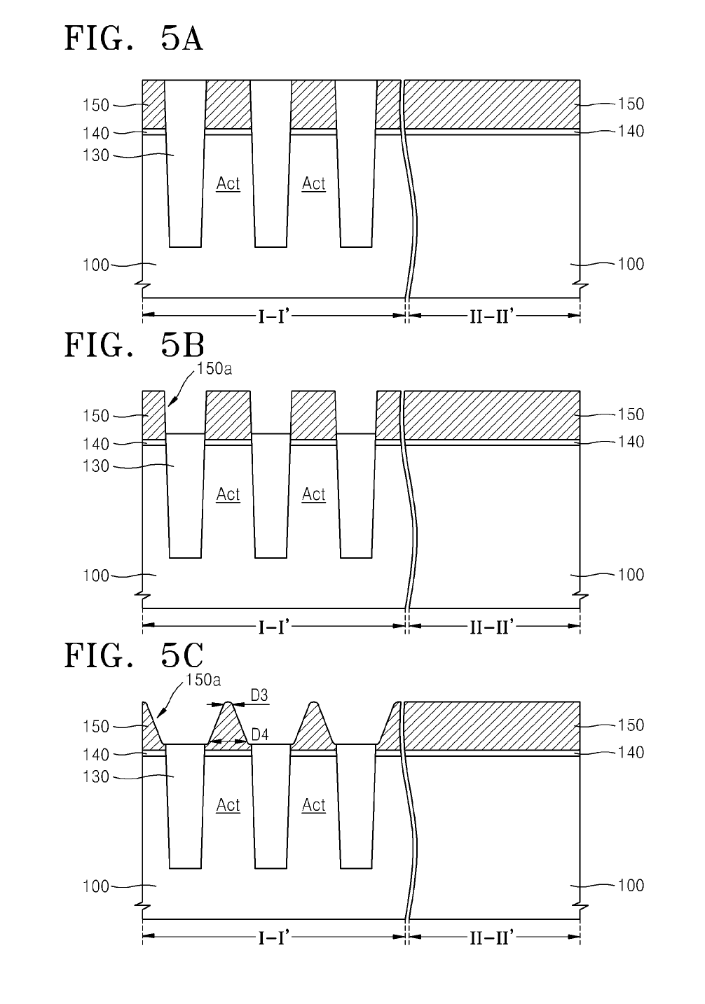

Both sidewalls 150a of the charge storage layer 150 have slopes such that they are not perpendicular to the extension directions of the word lines WL1, WL2, WLn−1, and WLn. Accordingly, an upper width D3 of the charge storage layers 150 may be less than a lower width D4 thereof. The lower width D4 of the charge storage layers 150 may be less than the width of the active regions Act when compared to the non-volatile memory device shown in FIG. 2. This is a structural difference caused by methods of manufacturing memory devices and will be described with reference to FIGS. 5A to 5C in detail. In addition, the upper width D3 of the charge storage layers 150 may be less than the upper width Dl of the charge storage layers 150 shown in FIG. 2, and the lower width D4 of the charge storage layers 150 may also be less than the lower width D2 of the charge storage layers 150 shown in FIG. 2. In one embodiment, the ratio of the lower width D4 to the upper width D3 may be, for example, 2.4:1 to 2.0:1 (e.g., in one embodiment, the ratio is 2.2:1). Thus, an interval between adjacent charge storage layers 150 increases. In one embodiment, D3 is a width at a top surface of charge storage layers 150, and D4 is a width at a height coplanar with a top surface of device isolation layers 130. However, D3 may refer to another width at different top portion of charge storage layers 150, and D4 may refer to a width at a different portion of the charge storage layers 150.

In the non-volatile memory device according to the present embodiment, since the sidewalls 150a of the charge storage layers 150 have slopes, intervals between adjacent charge storage layers 150 increase, thereby improving interference characteristics between adjacent memory cells. In addition, a contact area between the charge storage layer 150 and the blocking insulating layer 160 increases due to the device isolation layers 130 that is formed low, so that a coupling ratio may be increased.

FIGS. 5A to 5C are cross-sectional views of the non-volatile memory device of FIG. 4 for describing a method of manufacturing the non-volatile memory device. FIGS. 5A to 5C are respectively cross-sectional views taken along lines I-I′ and II-II′ of FIG. 4.

Referring to FIG. 5A, the tunneling insulating layer 140 and the charge storage layer 150 are formed on the substrate 100. Then, the charge storage layer 150, the tunneling insulating layer 140 and the substrate 100 are etched using a photoresist pattern (not shown) to form trenches (not shown). The trenches may be formed using an anisotropic etching process, for example, a plasma etch process. According to the present embodiment, trenches are formed after the tunneling insulating layer 140 and the charge storage layer 150 are formed, which is distinguished from the memory device shown in FIG. 2 described with reference to FIGS. 3A to 3E.

All of the trenches are filled with an insulating material, and a planarization process may be performed. The planarization process may be, for example, a CMP process. The trenches may be planarized by the planarization process to form the device isolation layers 130 having the same height as the charge storage layer 150. The active regions Act may be defined by the device isolation layers 130.

Referring to FIG. 5B, the device isolation layers 130 are subjected to a recess process. The recess process may include, for example, an anisotropic etching process. Due to the recess process, sidewalls 150a of the charge storage layer 150 may be exposed. In one embodiment, the upper surface of the recessed device isolation layers 130 may be higher than the upper surface of the tunneling insulating layers 140 at both sides thereof.

Referring to FIG. 5C, the sidewalls 150a of the charge storage layers 150 exposed by the recess process may be partially removed. Accordingly, the sidewalls 150a of the charge storage layers 150 have slopes. For example, each of the slopes of the sidewalls 150a may slope inward toward a top in a width direction of the charge storage layer 150. In addition, the slope of the sidewalls may be a continuous, constant, or nearly constant slope (i.e., a smooth curve) that does not have abrupt changes between a lower width D4 and an upper width D3 of the charge storage layer 150. The sidewalls 150a may be removed such that slopes are formed from the lowest exposed sidewall 150a of the charge storage layer 150 to the highest sidewall 150a of the charge storage layer 150. An upper width D3 of the charge storage layer 150 may be less than a lower width D4 thereof. Thus, an interval between adjacent charge storage layers 150 increases.

According to the present embodiment, the sidewalls 150a may be removed by a dry cleaning process using NF₃ gas and NH₃ gas. The dry cleaning according to the present embodiment is a dry etching process and may use plasma, (e.g., remote plasma), to activate the NF₃ gas and the NH₃ gas. For example, the plasma power may equal to or greater than 30 W.

As the integration density of semiconductor memory devices increases, permeation and release of a cleaning agent are difficult in a structure having a big height difference due to a wet cleaning process. Thus, characteristics of the semiconductor memory devices may deteriorate. However, the deterioration may not occur by the dry cleaning used herein, since the cleaning process is performed using gas. In addition, a large amount of wafers may be cleaned by a single cleaning process, thereby improving cleaning efficiency.

The processes described above with reference to FIGS. 3H and 3I may be performed to form a non-volatile memory device as shown in FIG. 4.

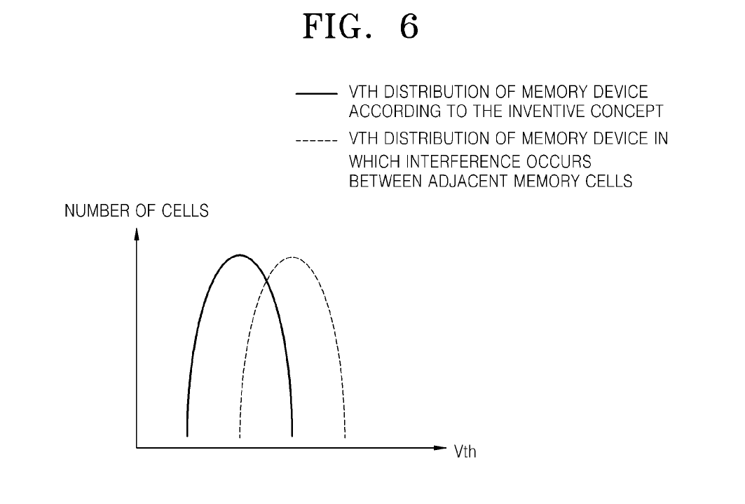

FIG. 6 is a graph for describing a threshold voltage characteristic of a non-volatile memory device according to certain embodiments.

FIG. 6 shows distributions of a threshold voltage (Vth) of a memory device according to the present disclosure and a threshold voltage (Vth) of a memory device in which interference occurs between adjacent memory cells according to a conventional art. As an interval between adjacent memory cells decreases in a flash memory device including a conductive charge storage layer, interference of floating gates between adjacent memory cells increases. Accordingly, the threshold voltage (Vth) increases, and thus a distribution curve of the threshold voltage (Vth) of a memory cell transistor is shifted to a right side.

In a non-volatile memory device manufactured using the method according to the present disclosure, the interval between floating gates of adjacent memory cells may be increased. Thus, an increase in the threshold voltage (Vth) may be reduced.

In addition, the non-volatile memory device manufactured using the method according to the present disclosure has excellent reliability such as high endurance and excellent high temperature storage (HTS) characteristics.

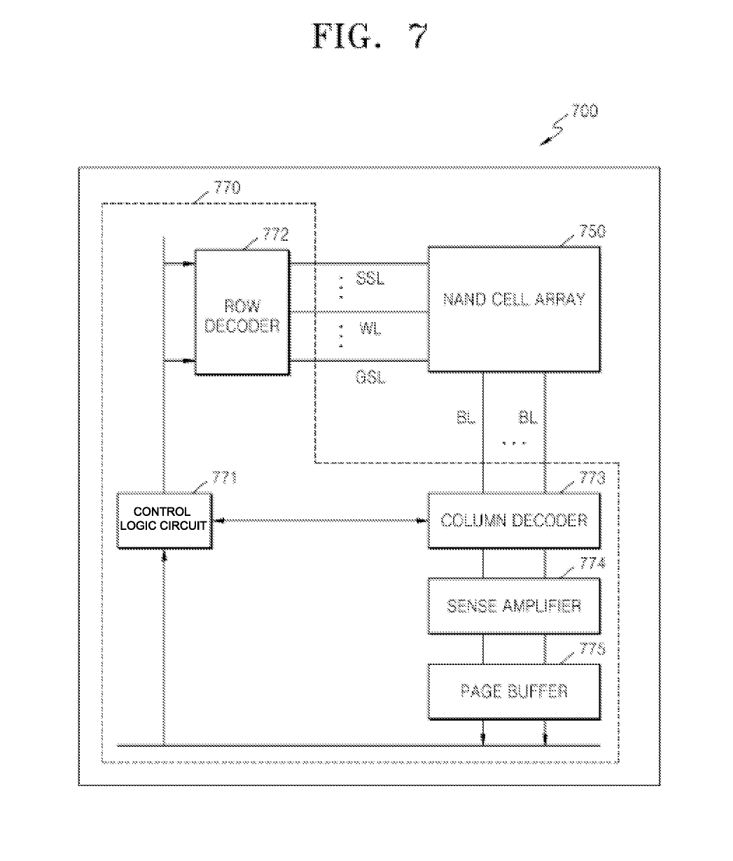

FIG. 7 is a schematic block diagram of the non-volatile memory device according to another exemplary embodiment.

Referring to FIG. 7, in a non-volatile memory device 700, a NAND cell array 750 may be connected to a core circuit 770. For example, the NAND cell array 750 may include any one of the non-volatile memory devices described with reference to the figures described above. The core circuit 770 may include a control logic circuit 771, a row decoder 772, a column decoder 773, a sense amplifier 774, and a page buffer 775.

The control logic circuit 771 may communicate with the row decoder 772, the column decoder 773, and the page buffer 775. The row decoder 772 may communicate with the NAND cell array 750 via a plurality of string selection lines SSL, a plurality of word lines WL, and a plurality of ground selection lines GSL. The column decoder 773 may communicate with the NAND cell array 750 via a plurality of bit lines BL. The sense amplifier 774 is connected to the column decoder 773 when a signal is output from the NAND cell array 750 and is not connected to the column decoder 773 when a signal is input to the NAND cell array 750.

For example, the control logic circuit 771 sends a row address signal to the row decoder 772, and the row decoder 772 decodes the row address signal and sends the signal to the NAND cell array 750 via the string selection lines SSL, the word lines WL, and the ground selection lines GSL. The control logic circuit 771 sends a column address signal to the column decoder 773 or the page buffer 775, and the column decoder 773 decodes the column address signal and sends the signal to the NAND cell array 750 via the plurality of bit lines BL. A signal of the NAND cell array 750 is transmitted to the sense amplifier 774 via the column decoder 773, amplified in the sense amplifier 774, and transmitted to the control logic circuit 771 via the page buffer 775.

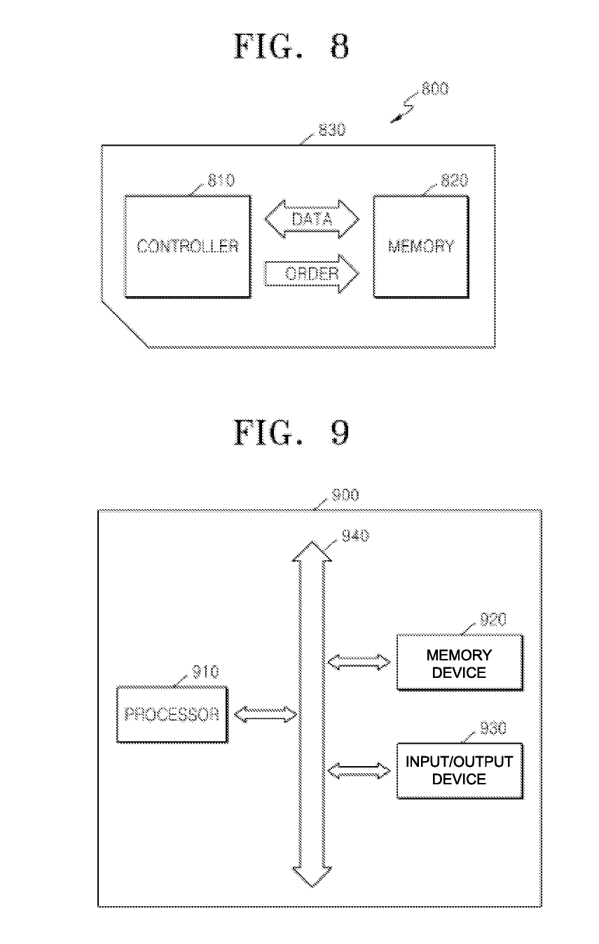

FIG. 8 schematically shows a memory card according to an exemplary embodiment.

Referring to FIG. 8, a memory card 800 includes a controller 810 and a memory 820 embedded in a housing 830. The controller 810 and the memory 820 exchange an electrical signal. For example, the memory 820 and the controller 810 may exchange data according to an order from the controller 810. Accordingly, the memory card 800 stores data in the memory 820 or outputs data from the memory 820. The memory may include, for example, a semiconductor memory chip, package, or package-on-package, etc.

For example, the memory 820 may include any one of the non-volatile memory devices described with reference to the figures described above. The memory card 800 may be used as a data storage medium of a variety of portable devices. For example, the memory card 800 may include a multi media card (MMC) or a secure digital card (SD).

FIG. 9 is a block diagram illustrating an electronic system 900 according to an exemplary embodiment.

Referring to FIG. 9, the electronic system 900 may include a processor 910, an input/output device 930, and a memory device 920, which may exchange data using a bus 940. The processor 910 may execute a program and control the electronic system 900. The input/output device 930 may be used to input or output data from the electronic system 900. The electronic system 900 may be connected to an external device, e.g., a personal computer or a network, in order to exchange data with the external device. The memory device 920 may store code and data for operating the processor 910. For example, the memory device 920 may include any one of the non-volatile memory devices described with reference to the figures described above. The memory device may include, for example, a semiconductor memory chip, package, or package-on-package, etc

The electronic system 900 may be used in a variety of electronic control devices requiring the memory device 920, such as a mobile phone, a MP3 player, a navigation device, a solid state disk (SSD), and household appliances.

While the present disclosure has been particularly shown and described with reference to exemplary embodiments thereof, it will be understood that various changes in form and details may be made therein without departing from the spirit and scope of the following claims.

1. A method of manufacturing a non-volatile memory device, the method comprising:
providing a substrate on which a plurality of charge storage layers that are electrically separated from each other by device isolation layers are formed;
recessing the device isolation layers such that an uppermost portion of the device isolation layers is lower than an uppermost portion of the charge storage layers; and
dry cleaning first and second sides of each of the charge storage layers that are exposed by the device isolation layers by using a cleaning agent comprising NF₃ gas.

2. The method of claim 1, wherein an upper width of each of the charge storage layers becomes less than a lower width of each of the charge storage layers due to the dry cleaning.

3. The method of claim 1, wherein the cleaning agent further comprises NH₃ gas, wherein the amount of the NF₃ gas is greater than that of the NH₃ gas.

4. The method of claim 3, wherein the volume ratio of the NF₃ gas to the NH₃ gas is in a range of 5:1 to 10:1.

5. The method of claim 3, wherein the dry cleaning is performed at a temperature in a range of 30° C. to 60° C.

6. The method of claim 3, wherein the dry cleaning is performed by using a plasma to activate the NF₃ gas and the NH₃ gas.

7. The method of claim 6, wherein the plasma power is equal to or greater than 30 W.

8. The method of claim 1, further comprising removing an oxide from the surface of the charge storage layers using hydrofluoric acid (HF) before the dry cleaning.

9. The method of claim 1, wherein the cleaning agent has an etch selectivity with respect to the charge storage layers which is greater than that with respect to the device isolation layers.

10. The method of claim 9, wherein for the etch selectivity of the cleaning agent between the charge storage layers and the device isolation layers is equal to or greater than 4:1.

11. The method of claim 1, wherein the recessing of the device isolation layers comprises:
a first recessing by which the device isolation layers are recessed to a predetermined depth; and
a second recessing by which the device isolation layers are recessed to be lower than the uppermost portion of the charge storage layers.

12. The method of claim 11, wherein the dry cleaning is performed between the first recessing and the second recessing.

13. The method of claim 1, wherein the providing of the substrate comprises:
forming a stack structure in which a pad layer and a mask layer are sequentially stacked on the substrate;
forming trenches in the substrate by partially etching the stack structure and the substrate;
forming device isolation layers in the trenches; and
removing the pad layer and the mask layer at both side of the device isolation layers and forming a plurality of charge storage layers electrically separated from each other by the device isolation layers.

14. The method of claim 1, wherein the providing of the substrate comprises:
sequentially stacking a tunneling insulating layer and a charge storage layer on the substrate;
forming trenches in the substrate by partially etching the tunneling insulating layer, the charge storage layer, and the substrate; and
forming device isolation layers in the trenches to electrically separate the charge storage layers from each other.

15. A method of manufacturing a non-volatile memory device, the method comprising:
providing a substrate on which a plurality of charge storage layers that are electrically separated from each other by device isolation layers are formed; and
recessing the device isolation layers such that an uppermost portion of the device isolation layers is lower than an uppermost portion of the charge storage layers,
wherein first and second sides of each of the charge storage layers are etched while recessing the device isolation layers.

16. The method of claim 15, wherein the recessing of the device isolation layers is performed using a cleaning agent comprising NF₃ gas and NH₃ gas.

17. The method of claim 16, wherein an upper width of each of the charge storage layers becomes less than a lower width of each of the charge storage layers due to the recessing.

18-20. (canceled)
